(19) United States
(12) Patent Application Publication
(10) Pub. No.: US 2008/0260090 A1
(43) Pub. Date: Oct. 23, 2008

(54) Shift register and shift registering apparatus

(75) Inventors: Ko-Yang Tso, Jhonghe City (TW); Hui-Wen Miao, Hsinchu (TW); Chin-Chieh Chao, Hsinchu City (TW)

Correspondence Address: RABIN & Berdo, PC, 1101 14TH STREET, NW, SUITE 500, WASHINGTON, DC, 20005, US

(73) Assignee: Raydium Semiconductor Corporation, Hsinchu (TW)

(21) Appl. No.: 12/078,604

(22) Filed: Apr. 2, 2008

(30) Foreign Application Priority Data
Apr. 20, 2007 (TW) 096114165

(51) Int. Cl. G11C 19/00

(52) U.S. Cl. 377/78; 377/81

(57) ABSTRACT

A shift register is provided for use in a data driver. The shift register includes a shift registering unit. The shift registering unit selectively receives a clock signal. The shift registering unit includes a flip-flop; and a first selection circuit. The first selection circuit selectively sends the clock signal to the flip-flop according to a first selection signal, wherein before the flip-flop receives a data signal that is enabled, the first selection circuit sends the clock signal to the flip-flop according to the first selection signal so that the flip-flop correctly outputs the enabled data signal according to the clock signal.

This application claims the benefit of Taiwan application Serial No. 96114165, filed Apr. 20, 2007, the subject matter of which is incorporated herein by reference.

### BACKGROUND OF THE INVENTION

1. Field of the Invention

The invention relates in general to a shift register for a data driver and more particularly to a shift register with power saving capability.

2. Description of the Related Art

FIG. 1 shows a partial structure of a conventional shift register including a number of flip-flops (FFs). As indicated in FIG. 1, when the FF 110 receives an initial data signal DT that is enabled, the FF 110 outputs a data signal Q1 that is enabled according to an input clock signal CK. After receiving the enabled data signal Q1, the FF 120 outputs an enabled data signal Q2 to the next FF 130. In the similar manner, shift registers output respective enabled data signals to the next circuit, such as a line latch, so that correct pixel data, for example, can be latched.

For the internal flip-flops of the shift register, both the flip-flop outputting the enabled data signal and the flip-flop receiving this signal need to operate. Inevitably, the flip-flops operate in response to the clock signal and thus consume energy, which may be unnecessary, regardless of whether the flip-flop receives or outputs the enabled data signal.

### SUMMARY OF THE INVENTION

The invention is directed to a shift register. For each shift registering unit of the shift register, selection circuitry is used to individually control whether to output a clock signal to a flip-flop of each shift registering unit. For the shift registering unit which will receive the enabled data signal, the selection circuitry sends the clock signal CK to the flip-flop of the shift registering unit so that the flip-flop of the shift registering unit can receive the enabled data signal. After the flip-flops of the shift registering unit all output the enabled data signals or when it is still early for the flip-flop of the shift registering unit to receive the enabled data signal, the selection circuitry stops sending the clock signal CK to the flip-flop of the shift registering unit so that the flip-flop of the shift registering unit is disabled. In this way, power saving can be achieved.

According to a first aspect of the invention, a shift register is provided for use in a data driver. The shift register includes a shift registering unit. The shift registering unit selectively receives a clock signal. The shift registering unit includes a flip-flop; and a first selection circuit. The first selection circuit selectively sends the clock signal to the flip-flop according to a first selection signal, wherein before the flip-flop receives a data signal that is enabled, the first selection circuit sends the clock signal to the flip-flop according to the first selection signal so that the flip-flop correctly outputs the enabled data signal according to the clock signal.

According to a second aspect of the invention, a shift register apparatus is provided for use in a data driver. The shift registering apparatus includes a shift register. The shift register selectively receives a clock signal. The shift register includes a first selection circuit and a shift registering unit. The first selection circuit selectively sends the clock signal according to a first selection signal. The shift registering unit includes a flip-flop and a second selection circuit. The second selection circuit selectively sends the clock signal sent from the first selection signal to the flip-flop according to a second selection signal. Before the flip-flop receives a data signal that is enabled, the first selection circuit sends the clock signal to the second selection circuit according to the first selection signal. Before the flip-flop receives the data signal that is enabled, the second selection circuit sends the clock signal to the flip-flop according to the second selection signal so that the flip-flop correctly outputs the enabled data signal according to the clock signal.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a partial structure of a conventional shift register.

FIG. 2 shows a block diagram of a shift registering apparatus according to an embodiment of the invention.

FIG. 3 shows a block diagram illustrating a partial structure of the shift register in FIG. 2.

FIG. 4 shows a partial structure of a bi-directional shift register 400 according to another embodiment of the invention.

### DETAILED DESCRIPTION OF THE INVENTION

An embodiment of the invention is directed to a shift registering apparatus for use in a data driver. The shift registering apparatus includes a shift register for selectively receiving a clock signal. The shift register includes a first selection circuit and a shift registering unit. The first selection circuit selectively sends the clock signal according to a first selection signal. The shift registering unit includes a flip-flop and a second selection circuit. The second selection circuit selectively sends the clock signal sent from the first selection signal to the flip-flop according to a second selection signal. Specifically, before the flip-flop receives a data signal that is enabled, the first selection circuit sends the clock signal to the second selection circuit according to the first selection signal. In addition, before the flip-flop receives the data signal that is enabled, the second selection circuit sends the clock signal to the flip-flop according to the second selection signal so that the flip-flop correctly outputs the enabled data signal according to the clock signal.

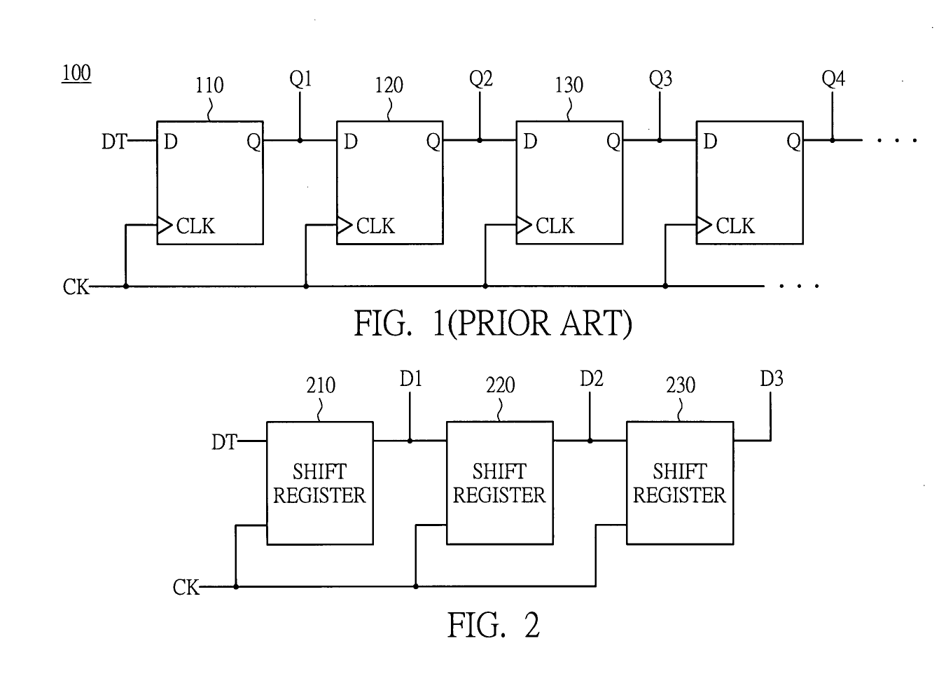

A shift registering apparatus 200 in FIG. 2 indicates the embodiment of the invention. The shift registering apparatus 200 includes shift registers 210, 220, and 230. The shift registers 210 to 230 all receive a clock signal clock signal CK. The shift register 210 receives an enabled data signal DT and outputs an enabled data signal D according to the clock signal CK. The shift register 220 receives the enabled data signal D1 and outputs an enabled data signal D2 according to the clock signal CK. The shift register 230 receives the enabled data signal D2 and outputs an enabled data signal D3 according to the clock signal CK.

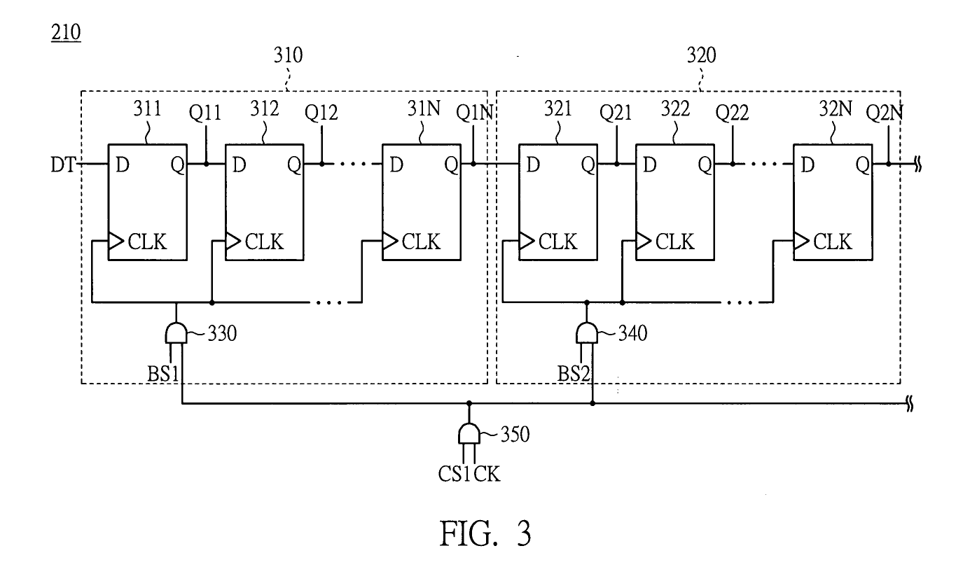

A partial structure of the shift register 210, as indicated in FIG. 2, is shown in FIG. 3. The shift register 210 includes at least one shift registering unit and a first selection circuit 350. Each shift registering unit includes N flip-flops (FFs) and a second selection circuit, where N is a positive integer. In this embodiment, the shift register 210 includes a shift registering unit 310 and a shift registering unit 320.

The shift registering unit 310 includes FFs 311, 312 to 31N and a second selection circuit 330. The shift registering unit 320 includes FFs 321, 322 to 32N and a second selection circuit 340.

The first selection circuit 350 selectively outputs the clock signal CK to the second selection circuits 330 and 340 according to a selection signal CS1. When the first selection circuit 350 outputs the clock signal CK to the second selection circuits 330 and 340, the second selection circuits 330 and 340 sends the clock signal CK to the two groups of FFs 311 to 31N and 321 to 32N according to the selection signals BS1 and BS2, respectively. In this embodiment, the first selection circuit 350, second selection circuits 330 and 340 can be implemented as logical circuitry such as AND gates, for example.

An example of the operation of the first selection circuit 350 of the shift register is described. Before the first FF 311 of the first shift registering unit 310 of the shift register 210 will or is about to receive the enabled data signal DT, the selection signal CS1 is at a logic level of “1”. As a result, the first selection circuit 350 is enabled to output the clock signal CK to the second selection circuits 330 and 340 so that all of the FFs of the shift register 210 can correctly output the enabled data signals.

After the last FF of the last shift registering unit of the shift register 210 outputs the enabled data signal D1, the FFs of the shift register 210 will not need operation any longer. The selection signal CS1 is then set to a logic level of “0”. As such, the first selection circuit 350 stops outputting the clock signal CK to the second selection circuits 330 and 340 so as to disable the FFs of the shift register 210, resulting in saving power.

Similar to the operation of the first selection circuit 350, before the first FF (not shown) of the first shift registering unit of the shift register 220 receives the enabled data signal D1, a first selection signal CS2 (not shown) is set to a logic level of “1”. Thus, the first selection circuit (not shown) of the shift register 220 is enabled to output the clock signal CK to the second selection circuit (not shown) of the shift register 220 so that all of the FFs of the shift register 220 correctly output the enabled data signals.

An example of the operation of the shift registering unit 310 and shift registering unit 320 is depicted here. Before the first FF 311 of the shift registering unit 310 receives the enabled data signal DT, the first selection circuit 350 of the shift register 210 sends the clock signal CK to the second selection circuit of the FFs of the shift register 210.

After the first selection circuit 350 outputs the clock signal CK to the second selection circuit of each shift registering unit and before the FF 311 of the shift registering unit 310 receives the enabled data signal DT, the second selection circuit 330 of the shift registering unit 310 sends the clock signal CK to the FFs 311 to 31N according to the selection signal BS1. As a result, the FF 311 is able to correctly receive the enabled data signal DT, and output an enabled data signal Q11 to the next FF 312. The other FFs of the shift registering unit 310 operate likewise.

Thus, when receiving an enabled data signal orderly, the FFs 311 to 31N can output the enabled data signals correctly according to the clock signal CK. In this embodiment, the selection signal BS1 is at a logic level of “1” and thus the second selection circuit 330 outputs the clock signal CK.

After the last FF 31N of the shift registering unit 310 outputs an enabled data signal Q1N, the FFs 311 to 31N all have outputted their enabled data signals and thus the FFs 311 to 31N will not need operation any longer. As a result, the second selection circuit 330 of the shift registering unit 310 stops sending the clock signal CK to the FFs 311 to 31N according to the selection signal BS1 so as to disable the FFs 311 to 31N, thereby saving power. In this embodiment, the selection signal BS1 is at a logic level of “0” then and the second selection circuit 330 stops outputting the clock signal CK.

For example, the enabled data signal Q1N is the enabled data signal D1 in FIG. 2 in this embodiment.

With respect to the shift registering unit 320, before the FF 321 receives the enabled data signal Q1N sent from the FF 31N, the second selection circuit 340 sends the clock signal CK to the FFs 321 to 32N of the shift registering unit 320. The selection signal BS2 is at a logic level of “1” then so that the second selection circuit 340 outputs the clock signal CK.

Thus, when receiving the enabled data signal Q1N, the first FF 321 of the shift registering unit 320 can send an enabled data signal Q21 to the next FF 322 correctly. Similarly, the other FFs of the shift registering unit 320 also send the enabled data signals to the respective next FFs.

For the shift register as in this embodiment, the following approach can be employed to control whether to output a clock signal to FFs of each shift registering unit. The control approach is exemplified by the operation of the shift registering unit 310 and shift registering unit 320 as follows.

Before the j-th FF of the shift registering unit 310, such as the (N−1)th FF, receives an enabled data signal, the selection signal BS2 is at a logic level of “0”. The second selection circuit 340 of the shift registering unit 320, according to the selection signal BS2, does not output the clock signal CK to the shift registering unit 320 so that the FFs 321 to 32N of the shift registering unit 320 are disabled, thereby saving power.

When the j-th FF of the shift registering unit 310 receives an enabled data signal, the selection signal BS2 is switched to a logic level of “1”. The second selection circuit 340 of the shift registering unit 320, according to the selection signal BS2, sends the clock signal CK to the FFs 321 to 32N of the shift registering unit 320. As a result, the FF 321 is enabled to, after receiving the enabled data signal Q1N, correctly output the enabled data signal Q21 to the next FF 322, according to the clock signal CK. The other FFs of the shift registering unit 320 can operate in a similar manner as mentioned above and thus their operation will not repeated for the sake of brevity.

When the y-th FF of the shift registering unit 320, such as the second FF 322, receives an enabled data signal, all FFs of the shift registering unit 310 have outputted their enabled data signals and then all FFs will not need to operation any longer. Thus, the selection signal BS1 is switched to a logic level of “0”. The second selection circuit 330 of the shift registering unit 310 stops sending the clock signal CK to the FFs 311 to 31N of the shift registering unit 310 according to the selection signal BS1 so as to disable the FFs 311 to 31N, thereby saving power.

The structure and operation of the shift register 210 are illustrated as above. The structure and operation of the shift register 220 and second selection circuit 330 are similar to those of the shift register 210, and thus details will not be repeated for the sake of brevity.

In the embodiment, the selection signals CS1, BS1, and BS2 for the shift register 210 are enabled or disabled according to the clock signal CK. For example, the shift registering apparatus 200 includes three shift registers, each shift register includes M shift registering units, and each shift registering unit includes N FFs. Each FF receives or outputs the enabled data signal for the same period of the clock signal CK. The selection signal CS1 is enabled before the first FF of the first shift registering unit of the shift register 210 receives an enabled data signal. Conversely, the selection signal CS1 is switched to be disabled after the last FF of the last shift registering unit outputs the enabled data signal D1. Therefore, the selection signal CS1 is enabled for M×N periods every 3×M×N periods. The selection signal BS1 is enabled before the first FF 311 of the shift registering unit 310 receives an enabled data signal. Conversely, the selection signal BS1 is switched to be disabled after the last FF 31N outputs the enabled data signal. Therefore, the selection signal BS1 is enabled for N periods every 3×M×N periods. For the other shift registers and shift registering units, their selection signals are enabled or disabled according to the clock signal CK likewise.

In one embodiment, a signal detector is employed to generate the selection signals CS1, BS1, and BS2 for the shift register 210. The signal detector detects whether the selection signals selection signals CS1, BS1, and BS2 are enabled or not. For the other shift register, the signal detectors can also be used to output their selection signals and detect whether the selection signals are enabled or not.

In the above embodiment, the shift registering apparatus has three shift registers, for example. In practical applications, the apparatus may employ shift registers more than three ones. In other embodiments, a shift registering apparatus includes at least one shift register or more than three ones, and each shift register employs a selection circuit to determine whether to output a clock signal to its internal shift registering unit, according to a received or outputted enabled data signal, thereby saving power; all of these embodiments are also within the scope of the invention

The following discusses the advantage of the shift registering apparatus of the above embodiment. As compared to the conventional one, the shift registering apparatus according to the embodiment of this invention has the advantage of power saving. In this regard, it is noticed that conventionally, the clock signal is always provided to the registers regardless of whether the registers do receive an enabled data signal or not. Specifically, even if all FFs of the register have not received or outputted enabled data signals, the FFs is still operating and consuming power unnecessarily.

By contrast, the shift registering apparatus according to the above embodiment includes a number of registers, each of which corresponds to a first selection circuit to individually control whether to output a clock signal to internal shift registering units. For each shift register, the first selection circuit outputs the clock signal to the second selection circuit of the shift registering unit when the FFs will or is about to receive or output enabled data signals. When the FFs have not outputted enabled data signals or it is still early for the FFs to receive the enabled data signals, the first selection circuit stops outputting the clock signal to the second selection circuit. In this way, the shift registering apparatus according to the embodiment can save power as compared to the conventional one.

In addition, in the shift register, for each shift registering unit, the second selection circuit is employed to individually control whether to output the clock signal to the FFs of each shift registering unit. For the shift registering unit, its second selection circuit begins to send the clock signal to the internal FFs of the shift registering unit until the shift registering unit will or is about to receive the enabled data signal so that the FFs of the shift registering unit is able to receive the enabled data signals. When the FFs of the shift registering unit have outputted enabled data signals or it is still early for the FFs of the shift registering unit to receive the enabled data signals, the second selection circuit stops sending the clock signal to the FFs of the shift registering unit so that the FFs of the shift registering unit are disabled, thus resulting in saving power further.

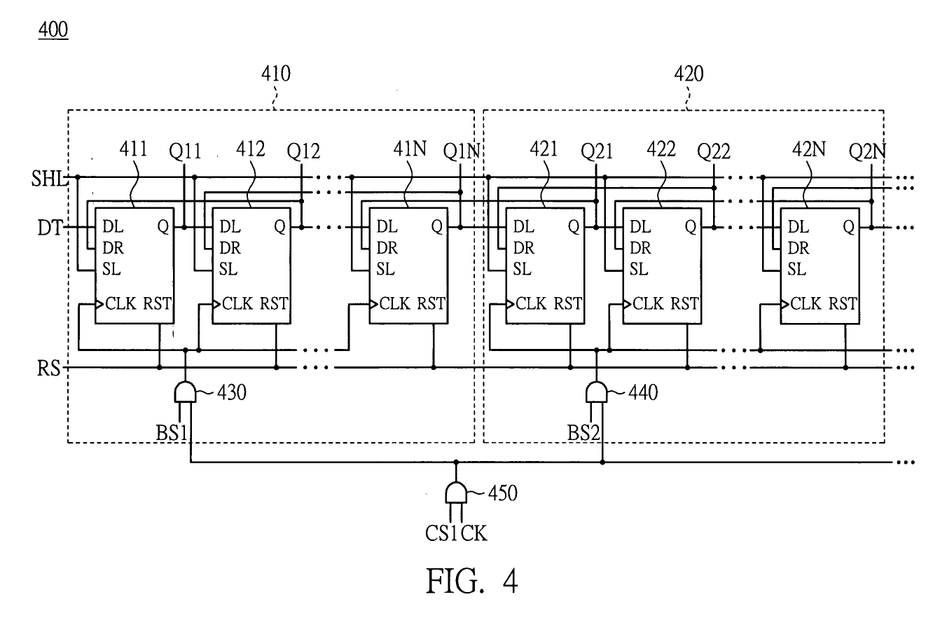

In another embodiment, a shift registering apparatus can be designed as a bi-directional shift registering apparatus including at least one bi-directional shift register. Each bi-directional shift register includes at least one shift registering unit. FIG. 4 illustrates a partial structure of a bi-directional shift register 400 according to the embodiment of the invention, wherein the bi-directional shift register 400 is illustrated with shift registering units 410 and 420. The shift register 400 includes a first selection circuit 450. The shift registering unit 410 includes a second selection circuit 430 and a number of FFs 411 to 41N. The shift registering unit 420 includes a second selection circuit 440 and a number of FFs 420 to 42N.

In addition, every FF receives a control signal SHL. The control signal SHL is employed to select the direction by which the data signal is sent. Each specific FF receives the data signal from the FF connected left or right to the specific FF.

Further, the first selection circuit 450 of the shift register 400 and the second selection circuits 430 and 440 operate in a manner similar to that mentioned above. For the sake of brevity, their operation will not be repeated.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A shift register, for use in a data driver, comprising:
a shift registering unit, for selectively receiving a clock signal, the shift registering unit comprising:
a flip-flop; and
a first selection circuit selectively sending the clock signal to the flip-flop according to a first selection signal;
wherein before the flip-flop receives a data signal that is enabled, the first selection circuit sends the clock signal to the flip-flop according to the first selection signal so that the flip-flop correctly outputs the enabled data signal according to the clock signal.

2. The shift register according to claim 1, wherein after the flip-flop outputs the enabled data signal, the first selection circuit stops outputting the clock signal to the flip-flop according to the first selection signal so as to disable the flip-flop.

3. The shift register according to claim 1, wherein the shift register includes M shift registering units, each of the M shift registering unit selectively receives the clock signal, each of the M shift registering units includes a plurality of flip-flops and the first selection circuit;
wherein before a first flip-flop of an i-th shift registering unit of the M shift registering unit receives an enabled data signal, the first selection circuit of the i-th shift registering unit sends the clock signal to the flip-flops of the i-th shift registering unit according to the first selection signal of the i-th shift registering unit so that the flip-flops of the i-th shift registering unit correctly output enabled data signals according to the clock signal;
wherein M is a positive integer and i is a positive integer not larger than M.

4. The shift register according to claim 2, wherein after a last flip-flop of the i-th shift registering unit outputs the enabled data signal, the first selection circuit of the i-th shift registering unit stops outputting the clock signal to the at least one flip-flop of the i-th shift registering unit according to the first selection signal of the i-th shift registering unit so as to disable the at least one flip-flop of the i-th shift registering unit.

5. The shift register according to claim 2, wherein each of the shift registering unit includes N flip-flops, when a j-th flip-flop of the i-th shift registering unit receives an enabled data signal, the first selection circuit of a (i+1)th shift registering unit of the shift registering units sends the clock signal to the N flip-flops of the (i+1)th shift registering unit according to the first selection signal of the (i+1)th shift registering unit so that the N flip-flops of the (i+1)th shift registering unit correctly outputs enabled data signals according to the clock signal;
wherein i is a positive integer smaller than M;
wherein N is a positive integer and j is a positive integer not larger than N.

6. The shift register according to claim 5, wherein before the j-th flip-flop of the i-th shift registering unit receives the enabled data signal, the first selection circuit of the (i+1)th shift registering unit does not send the clock signal to the N flip-flops of the (i+1)th shift registering unit according to the first selection signal of the (i+1)th shift registering unit so as to disable the N flip-flops of the (i+1)th shift registering unit.

7. The shift register according to claim 3, wherein each of the shift registering unit includes N flip-flops, when a j-th flip-flop of the (i+1)th shift registering unit receives an enabled data signal, the first selection circuit of the i-th shift registering unit stops sending the clock signal to the N flip-flops of the i-th shift registering unit according to the first selection signal of the i-th shift registering unit so as to disable the N flip-flops of the i-th shift registering unit;
wherein i, M, N, and j are positive integers, i is smaller than M, and j is not larger than N.

8. The shift register according to claim 3, wherein the shift register further comprises a second selection circuit for selectively outputting the clock signal to the first selection circuits of the shift registering unit according to a second selection signal.

9. The shift register according to claim 1, wherein the shift register is a bi-directional shift register.

10. A shift registering apparatus, for use in a data driver, comprising:
a shift register, for selectively receiving a clock signal, the shift register comprising:
a first selection circuit selectively sending the clock signal according to a first selection signal;
a shift registering unit comprising:
a flip-flop; and
a second selection circuit selectively sending the clock signal sent from the first selection signal to the flip-flop according to a second selection signal;
wherein before the flip-flop receives a data signal that is enabled, the first selection circuit sends the clock signal to the second selection circuit according to the first selection signal;
wherein before the flip-flop receives the data signal that is enabled, the second selection circuit sends the clock signal to the flip-flop according to the second selection signal so that the flip-flop correctly outputs the enabled data signal according to the clock signal.

11. The shift registering apparatus according to claim 10, wherein the shift registering apparatus further comprises P shift registers selectively receiving a clock signal, each of the P shift registers further comprises M shift registering units, each of the M shift registering units further comprises a plurality of flip-flops;
wherein before a first flip-flop of a first shift registering unit of a k-th shift register of the P shift registers receives an enabled data signal, the first selection circuit of the k-th shift register sends the clock signal to the second selection signal of each of the shift registering units of the k-th shift register according to the first selection signal of the k-th shift register;
wherein before a first flip-flop of an i-th shift registering unit of the M shift registering units of the k-th shift register receives an enabled data signal, the second selection circuit of the i-th shift registering unit sends the clock signal to the flip-flops of the i-th shift registering unit according to the second selection signal of the i-th shift registering unit so that the flip-flops of the i-th shift registering unit correctly output the enabled data signals according to the clock signal;
wherein P, k, M and i are positive integers, k and i are not larger than P and M, respectively.

12. The shift registering apparatus according to claim 11, wherein after the last flip-flop of the M-th shift registering unit of the k-th shift register outputs the enable data signal, the first selection circuit of the k-th shift register stops sending the clock signal to the second selection circuit of each of the shift registering units of the k-th shift register according to the first selection signal of the k-th shift register so as to disable the flip-flops of the M shift registering units of the k-th shift register.

13. The shift registering apparatus according to claim 12, wherein in the k-th shift register, after the last flip-flop of the i-th shift registering unit outputs the enable data signal, the second selection circuit of the i-th shift registering unit stops sending the clock signal to the flip-flops of the i-th shift registering unit according to the second selection signal of the i-th shift registering unit so as to disable the flip-flops of the i-th shift registering unit.

14. The shift registering apparatus according to claim 11, wherein each of the shift registering units of each of the shift registers comprises N flip-flops, in the k-th shift register, when a j-th flip-flop of the i-th shift registering unit receives an enabled data signal, the second selection circuit of an (i+1)th shift registering unit of the shift registering units sends the clock signal to at least one of the flip-flops of the (i+1)th shift registering unit according to the second selection signal of the (i+1)th shift registering unit so that the at least one of the flip-flops of the (i+1)th shift registering unit correctly outputs enabled data signals according to the clock signal;
wherein i, M, N, and j are positive integers, i is smaller than M and j is not larger than N.

15. The shift registering apparatus according to claim 14, wherein in the k-th shift register, before the j-th flip-flop of the i-th shift registering unit receives the enabled data signal, the second selection circuit of the (i+1)th shift registering unit does not send the clock signal to the flip-flops of the (i+1)th shift registering unit according to the second selection signal of the (i+1)th shift registering unit so as to disable the flip-flops of the (i+1)th shift registering unit.

16. The shift registering apparatus according to claim 14, wherein each of the shift registering unit of each of the shift registers includes N flip-flops, in the k-th shift register, when a j-th flip-flop of an (i+1)th shift registering unit of the shift registering units receives the enabled data signal, the second selection circuit of an i-th shift registering unit of the shift registering units stops sending the clock signal to the N flip-flops of the i-th shift registering unit according to the second selection signal of the i-th shift registering unit so that the N flip-flops of the i-th shift registering unit are disabled;
wherein i, M, N, and j are positive integers, i is smaller than M, and j is not larger than N.

17. The shift registering apparatus according to claim 11, wherein the shift register is a bi-directional shift register.
